(19) United States
(12) Patent Application Publication
(10) Pub. No.: US 2005/0270061 A1
(43) Pub. Date: Dec. 8, 2005

(54) Configurable logic circuit

(75) Inventor: Jan Otterstedt, Unterhaching (DE)

Correspondence Address: DARBY & DARBY P.C., P. O. BOX 5257, NEW YORK, NY, 10150-5257, US

(73) Assignee: Infineon Technologies AG, Munich (DE)

(21) Appl. No.: 11/147,414

(22) Filed: Jun. 6, 2005

(30) Foreign Application Priority Data
Jun. 4, 2004 (DE) 10 2004 027 372.3

(51) Int. Cl. H03K 19/173

(52) U.S. Cl. 326/38

(57) ABSTRACT

A configurable logic circuit having a plurality of logic blocks and a connecting structure, via which the logic blocks are interconnectable, wherein the logic blocks are implemented in dual rail technique.

### CROSS-REFERENCE TO RELATED APPLICATION

This application claims priority from German Patent Application No. 102004027372.3, which was filed on Jun. 4, 2004 and is incorporated herein by reference in its entirety.

### BACKGROUND OF THE INVENTION

1. Field of the Invention

The present invention relates to configurable logic circuits, such as FPGAs (FPGA=field programmable gate array), and their usage in security critical applications.

2. Description of the related art

Nowadays, many processes of daily life are controlled and influenced, respectively, by integrated circuits. Integrated circuits form, for example, a significant part of electronics in a car for controlling fuel injection, airbag release and many others. Nowadays, integrated circuits play also an important role in connection with cashless money transfer. Payment cards, chip cards or smartcards are examples for the usage of the integrated circuits in connection with cashless money transfer. The integrated circuits used there process secret data, which are to be known, for example, only to the card issuer and which are not to become known by a third party, such as a crypto key or the same.

One problem with cryptocontrollers is that they are subject to attacks of third parties after the card issue. One of these attacks is, for example, the DPA (DPA=differential power analysis) attack. In a DPA attack on an algorithm executed on an integrated circuit, the attacker draws conclusions about the processed data, such as the cryptographic key, from low data-dependent variations of the power consumption of the circuit. Depending on the used integration technology of the circuit, the data-dependent variations of the current consumption of the circuit originate, for example, from the switching operations of the inner transistors of the circuit.

In the case of CMOS technology, for example, every switching operation leads to a current pulse, several of which then overlap to the overall current consumption profile of the circuit. In order to prevent a successful DPA attack, a data dependence of the current consumption has to be provided. This is performed in hardwired crypto circuits mostly by the usage of so called dual rail logics, where it is ensured already on the single bit level that the overall power consumption is independent of the data to be processed, such as the cryptographic key. This is performed by coding every logical bit within the integrated circuit as a value pair on two different lines and rails, respectively, therefore the name dual rail logic. A bit of the value 1 is, for example, coded by one line being in a logic high state and the other line in a logic low state, and, vice versa, a bit of the value 0 is coded by one line being in a logic low state and the other in a logic high state. The result of a logical function of two dual rail coded bits is again a dual rail coded bit. These smallest logical functions combine then to a cryptocontroller or a cryptoprocessor within a cryptocontroller for implementing a cryptographic algorithm, by maintaining the described characteristic. Due to the coding of the individual bits into respectively opposite logic states, every bit leads to at least one switching operation when the bit value is altered.

In time, more and more attack variations have been developed for cryptocontrollers. Correspondingly, the number of protection mechanisms to be implemented in cryptocontrollers increased. The effect is that the cryptocontrollers are only difficult to implement on small areas. In mass produced articles, such as card ICs, the effort to integrate all security mechanisms in a hardwired and integrated circuit still pays due to the large numbers. Nowadays, until the card issue, a finished cryptocontroller passes merely through software transfers after its hardware production. First, for example, an operating system is loaded to the cryptocontroller. In the case of multiapplication chip cards, this operating system enables, for example, that several applications can run on the cryptocontroller without representing mutual security risks. A card issuer can then transfer his applications in the form of software onto the cryptocontroller and output the finished chip cards.

It would now be desirable for a producer of cryptocontrollers to implement configurable logic circuit parts within the cryptocontroller, for example in the form of a FPGA. Such a possibility would enable the cryptocontroller producer to offer a possibility to card issuers, to adapt parts of the cryptocontrollers, which have so far been hardwired due to performance requirements, to his specific custom needs.

The possible integration of FPGAs in security or chip card ICs has, for example, been suggested in DE 10105987 A1, whose applicant is also the applicant of the present application. The data processing apparatus suggested there comprises a function programmable logic circuit with a programming interface. The programming interface is protected from unauthorized access by an authorization control unit, so that a customized function adaptation of semiconductor devices can be performed, but a later alteration by unauthorized persons is effectively prevented.

However, in many security applications, the approach of DE 10105987 A1 to integrate a FPGA in a chip card IC comes up against limits due to the high security requirements. For many security critical applications, prior FPGA implementations are not suitable, since they are not DPA resistant, i.e. not secured against an attack with the methods of the differential-power analysis. In that way, current implementations of reconfigurable logic, such as FPGAs, can hardly ever be used on security or chip card ICs, since here a DPA security is required almost always.

Further, the integration of a common FPGA in a chip card is described in DE 10040854 A1, an implementation approach that consequently has the same disadvantages as the above-mentioned DE 10105987 A1. FR 2824648 describes the benefit of a conventional FPGA in that it describes that an equal function can be mapped onto a FPGA in a slightly different way.

Thus, so far, no reconfigurable logic, such as a FPGA, is integrated into security or chip card ICs. Any function already has to be predetermined in the design of the IC and has to be implemented in an appropriate form secured against DPA attacks. A later reconfiguration of prior chip card ICs is not possible, merely a change of software.

It would thus be desirable to have a reconfigurable logic circuit, which can be integrated into cryptocontrollers and security ICs, respectively, by fulfilling the requirements of DPA resistance of most crypto applications.

In a master paper titled “An investigation of differential power analysis attacks on FPGA-based Encryption systems” by Larry T. McDaniel III, DPA attacks on FPGA-based encryption systems are described in general.

### SUMMARY OF THE INVENTION

It is an object of the present invention to provide a more DPA resistant configurable logic circuit.

The present invention provides a configurable logic circuit having a plurality of logic blocks and a connecting structure, via which the logic blocks are interconnectable, wherein the logic blocks are implemented in dual rail technique.

### BRIEF DESCRIPTION OF THE DRAWINGS

These and other objects and features of the present invention will become clear from the following description taken in conjunction with the accompanying drawings, in which:

FIG. 1 is a block diagram of an FPGA according to an embodiment of the present invention;

FIG. 2 is a block diagram of a cryptocontroller with integrated FPGA according to an embodiment of the present invention; and

FIG. 3 is a portion of a block diagram of an FPGA according to a further embodiment of the present invention.

### DESCRIPTION OF THE PREFERRED EMBODIMENTS

It is a central idea of the present invention that a more DPA resistant or securer configurable logic circuit can be obtained by implementing logic blocks, which the configurable logic circuit comprises, and of which the same is constructed, respectively, in dual rail technique. Any possible configuration of the configurable logic circuit is then, as a whole, more DPA resistant, since it always processes all data in dual rail coded form.

The integration of such an inventive configurable logic circuit resistant against DPA attacks into a cryptocontroller and a security or chip card IC, respectively, yields several advantages compared to conventional hardwired cryptocontroller solutions. A customized function can be realized much more power efficient and performance efficient on a DPA resistant configurable logic circuit, such as an FPGA, realized on a cryptocontroller, than it is possible in software. Conversely, the possibility to realize DPA resistant circuits of security or chip card ICs as FPGA promises a much less expensive realization of a customized circuits than it is possible for a hardwired circuit.

According to a preferred embodiment of the present invention, the logic circuit cannot only be configured once, but is reconfigurable. Such a reconfigurability of a reconfigurable logic circuit realized on a cryptocontroller allows a card issuer or a customer to perform a reconfiguration also in the field or on site, respectively. Additionally, the know how of the customer is generally protected in the case of a configurability, because even the chip card producer does not know the configuration to which the customer sets the configurable logic circuit. Even in every chip of a series, the same function could be mapped in a slightly different way on the configurable logic circuit, such as the FPGA, integrated in the chip.

It is a further advantage of the present invention that due to its uniform realization, configurable logic circuits, such as FPGAs, are secure against a typical reverse engineering of the layout, since the realized circuit is merely in the configuration information, which is not part of the layout. As development of this principle, configurable logic circuits according to the present invention, such as particularly those integrated in chip cards, could be reconfigured sporadically in the field, such that still the same function and the same algorithm, respectively, is realized by the configurable logic circuit, but always in a different way. Opportunities therefore are, for example, terminal sessions, where the chip cards communicate with the terminals.

On the other hand, a chip card producer can offer new DPA resistant functions, without designing a new chip or producing new masks. Thus, this is also economically useful for smaller volumes, which would not justify an individual chip design. A further advantage is the very fast availability of chips with customized extensions.

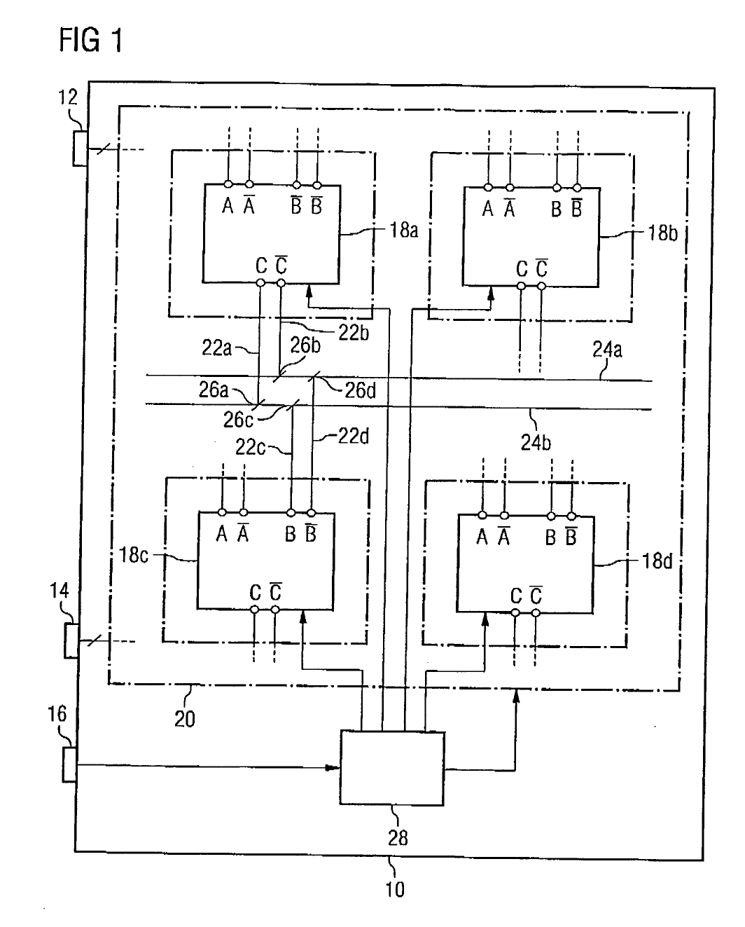

The FPGA indicated in FIG. 1 generally by reference number 10 comprises three interfaces to the outside, namely an input interface 12, an output interface 14 and programming and configuration interface 16, respectively. Via the input and output interfaces 12 and 14, the FPGA 10 can receive data from the outside and output them towards the outside depending on the input data and depending on the set configuration. The interfaces 12 and 14 can be serial or parallel interfaces, synchronously or asynchronously operating interfaces or the same. The programming interface 16 serves for setting the configuration of the FPGA 10, as will be discussed below in more detail.

Inside, the FPGA 10 is arranged in several logic units, so called logic blocks 18a, 18b, 18c and 18d. Merely exemplarily, four logic blocks 18a-18d are shown in FIG. 1. However, the FPGA 10 can also have any number of logic blocks 18-18d. Further, it is assumed merely exemplarily in FIG. 1 that the logic blocks 18a-18d are structured in the same way internally. But the logic blocks of the FPGA 10 can also vary.

The logic blocks 18a-18d represent the smallest units of the FPGA 10. Among them can be logic blocks which are configurable in their function. In FIG. 1, it is exemplarily assumed that all four logic blocks 18a-18d are configurable.

The logic blocks 18a-18d can act, for example, as look up tables. The n bit value at an n bit input of the logic blocks 18a-18d is used as index in a memory array (not shown) associated to the logic block, and the result, namely the value read out there is then output at an m bit output of the logic block. A configurable logic block can also perform the function of a multiplexer, which selects bits in a configurable way from an n bit input signal at an n bit input of the logic block, which it outputs at the m bit output of the logic block.

In FIG. 1, it is exemplarily assumed that the logic blocks 18a-18d have a 2 bit input for receiving the bits A and B and a 1 bit output for outputting the result C. Other granularities of FPGA 10 would also be possible, wherein the granularity indicates the size and complexity of its logic blocks 18a-18d. Particularly, an input with more bits and an output with more bits as well as a storage behavior of the logic block would be possible.

The logic blocks 18a-18d are implemented in dual rail technique. This means that every incoming and outgoing bit is dual rail coded. Thus, two inputs exist for every incoming bit, namely a non-inverted input and an inverted input. An incoming bit of the value 1 is for example equal to a logic high state at the non-inverted input and a logic low state at the inverted input. An incoming bit of the value 0 would then be, for example, equal to a logic low state at the non-inverted input and a logic high state at the inverted input. As has already been mentioned, it is exemplarily assumed in FIG. 1 that every logic block 18a-18d receives two bits and accordingly, every logic block 18a-18d in FIG. 1 comprises two pairs of a non-inverted and an inverted input, namely the non-inverted inputs A and B and the inverted inputs \overline{A} and \overline{B}. The same applies to an outgoing bit. Thus, according to the present specification, a logic block is to be considered as implemented in dual rail technique when dual rail coded bits at the inputs result again in a dual rail coded bit at the output or outputs, respectively, of the logic block. As mentioned above, the logic blocks 18a-18d in FIG. 1 have merely exemplarily a 1 bit output. Correspondingly, they comprise a non-inverted output C and an inverted output \overline{C}. A dual rail coded bit is input and output, respectively, at every inverted and non-inverted input and output, respectively.

The configurable logic blocks (CLB) and programmable logic blocks (PLB), respectively, 18a-18d can be interconnected and can also be connected to the input interface 12 and the output interface 14 via a connecting structure 20, which is schematically indicated in FIG. 1 by a dotted line. This means that the connecting structure 20 allows to connect a respective pair of non-inverted and inverted input and output, respectively, and 1 bit input and output, respectively, to one or several of a selection of the other 1 bit input and outputs, respectively, of the same and/or the other logic blocks. The connecting structure 20 allows also applying the bits at the input interface 12 in dual rail coded form to certain inputs of the logic blocks 18a-18d and in a corresponding way connecting the bit outputs of the logic blocks 18a-18d to corresponding bit positions of the output interface 14. Of course, it is possible that the connecting structure does not allow to connection of each one of the dual rail inputs 12, A and B, respectively, to every dual rail output C, and vice versa not each one of the dual rail outputs 14, C to each of the dual rail inputs A, B.

The connecting structure 20 is configurable, so that it can be adjusted, which input is connected to which output. Therefore, the connecting structure 20 comprises internal leads, each of which is connected to a respective input and output, respectively, and a respective rail, respectively, not inverted or inverted, and distribution lines. In FIG. 1, leads 22a, 22b, 22c and 22d for the bit output of the logic block 18a and the bit input B of the logic block 18c as well as two distribution lines 24a and 24b are shown exemplarily. Configurable and programmable interconnect points (CIP and PIP, respectively) are at node points between leads 22a-22d and distribution lines 24a-24d, which are controllable to connect a lead to a distribution line in a conductive way or not. Four CIPs 26a-26d are shown in FIG. 1. The CIPs can be designed as transistors or also as fuses or anti-fuses. The shown leads, distribution lines and CIPs are merely a small cutout of the connecting structure 20. Here, it is exemplarily assumed that the transistors are CIPs.

The FPGA 10 of FIG. 1 is exemplarily a reconfigurable FPGA. This means that it can be reconfigured after a configuration. For storing the configuration, the FPGA 10 comprises a memory 28. The memory 28 can, for example, be a volatile or a non-volatile memory. Exemplary embodiments for the memory 28 comprise RAM, flash or EEPROM. As indicated by arrows, outputs of the memory 28 are connected to the logic blocks 18a-18d and the connecting structure 20 to pass configuration data stored in the memory 28 in the form of configuration signals on to logic blocks 18a-18d and the connecting structure 20, respectively, in order to configure the same correspondingly. The configuration data provided in the memory 28 can be stored in the same via the programming interface 16, which is connected to an input of the memory 28.

Since the structure of the FPGA 10 of FIG. 1 has been described above, a configuration process will be discussed below. In a configuration, first the configuration data and programming data, respectively, are applied to the programming interface 16. These programming data are then stored in the memory 28 and passed on to the logic blocks 18a-18d and the connecting structure 20. More precisely, individual bits of the programming data switch individual transistors in the logic blocks 18a-18d to be conductive or non-conductive. With regard to the connecting structure 20, individual bits of the programming data switch, for example, the CIPs 26a-26d as switching means of the connecting structure 20 to be conductive or non-conductive. Then, in that instant, the FPGA 10 is configured.

In the configured state, applying an input signal to the input interface 12 leads to the input signal applied there being processed appropriately by the logic blocks 18a-18d in a way determined by the configuration in the memory 28, whereupon a corresponding output value is output at the output interface 14. The processing is DPA resistant, since all logic blocks are implemented in a dual rail technique, and the processed dual rail coded bits are passed on in this coded form by the connecting structure 20.

To minimize the number of programming bits of the programming data and to prevent errors in programming, which led to a DPA insecure processing, the connecting structure 20 is formed preferably such that it only allows the connection of a dual rail coded input/output with a dual rail coded bit input/output, but no individual connections between non-inverted and inverted terminals, respectively. In other words, any reconfiguration and change of a bit in the programming data, respectively, relating to the setting of the connecting structure 20 always leads one pair of non-inverted and inverted terminals is connected in a different way than previously, for example both are no longer connected to a respective distribution line or are only now connected to a distribution line. Related to the exemplary example of FIG. 1, for example, the CIPs 26a and 26b could only be reconfigured together, but never individually. The same applies to the CIPs 26c and 26d.

In relation to all circuit parts of the FPGA 10 relating to the configuration, it can be said that the same can be designed in a single rail technique, since the same do not contribute to the power consumption during operation of the FPGA 10, i.e. in the configured state, which means when the secret information is processed, and thus cannot reveal the processing of the secret data via DPA attacks. Accordingly, this applies to the circuit parts 28, 20 and the internal transistors and configuration circuit parts, respectively, of switching blocks 18a-18d.

Further, it should be noted that preferably the connecting structure 20 is disposed such that in any possible configuration any bit terminal is connected to another bit terminal in such a way that both the connecting path and the number of CIPs between the non-inverted terminal of a dual rail terminal on the one hand and the inverted terminal of the dual rail terminal on the other hand have the equal length or are equal, respectively. This prevents an accidental data dependence in the current consumption of the FPGA 10 occurring despite dual rail coding of the bits, which could be caused by reloadable capacities of different amounts. In the example of FIG. 1, this is achieved by arranging the logic blocks 18a-18d in columns and rows, the distribution lines running in row direction and the leads running in column direction.

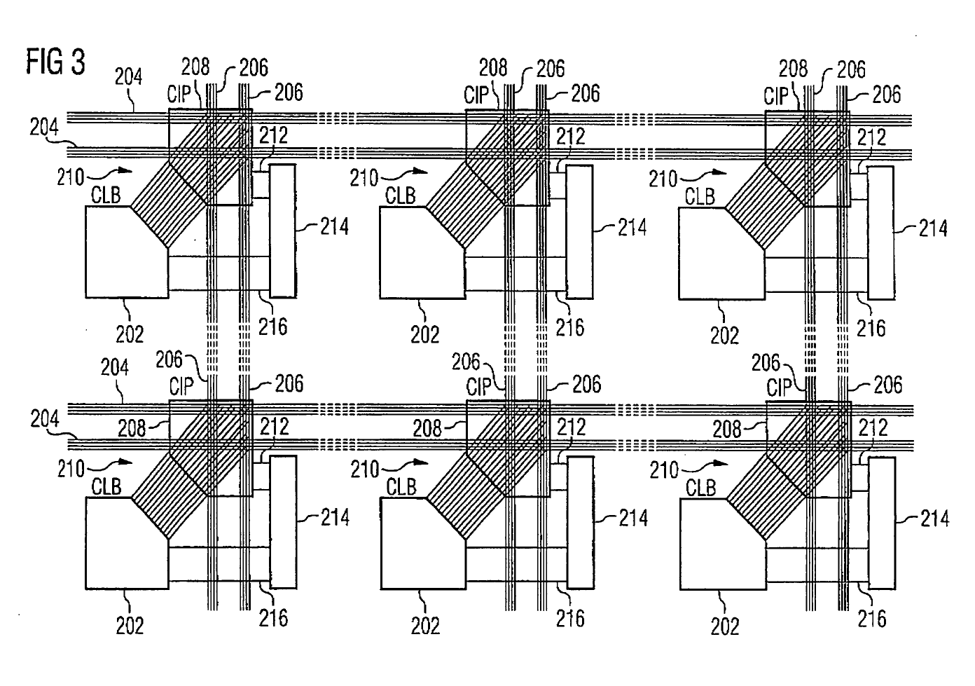

The structure of such FPGAs can also be designed in a different way. FIG. 3 shows an embodiment of a portion of an FPGA, where CLBs 202 are arranged in columns and rows, wherein both distribution lines 204 running in row direction between the CLBs 202 and distribution lines 206 running in column direction between the CLBs 202 are provided as part of the connecting structure. At the cross points of the distribution lines 204, 206 configurable interconnect points and CIPs 208, respectively, are provided, which are configurable to connect the pair of the distribution lines 204 or a pair of the distribution lines 206 to a pair of leads 210, which are again connected to dual rail inputs of the CLBs 202. The configuration of the CIP 208 is controlled via control lines 212 of a respectively associated configuration block 214. The configuration block 214 associated to a certain CIP 208 is connected to control and configuration inputs of the associated CLB 202 via control lines 216, which are also configurable.

The configuration blocks 214 control the configuration of the associated CIP 208 and associated CLB 202 via configuration data which can be input from outside via a configuration terminal of the FPGA. All possible configuration data of all configuration blocks 214 always result in a configuration of the FPGA of FIG. 3, where dual rail coded signals are transmitted on the leads by maintaining their dual rail coding and reach and leave the CLBs, respectively. In other words, in every possible configuration, it is ensured that all these dual rail coded signals are transmitted further as dual rail coded signal via the distribution lines 204 via pairs of distribution lines. Further, independent of the configuration, it is ensured that both rails of a dual rail coded signal transmitted via the connecting structure have the equal length and lead across the same number of CLBs. In other words, in every possible configuration, the leads 210 can merely be connected with predetermined pairs of distribution lines 204 and 206, respectively, and these pairs of distribution lines 204, 206 can also again only be connected within these pairs by the CIPs 208, but not independent of each other for different configurations.

The control signals, which are transmitted via the control lines 212 and 216, respectively, are transmitted on simple lines, i.e. single rail coded, which means with a coding where the first logic state on a line represents a first value of the signal to be transmitted, while a second state different to the first state on the same line represents a second value of the signal to be transmitted differing from the first value. This is possible since these signals are only changed once during configuration, and remain otherwise unchanged and thus do not contribute to the power consumption.

In other words, the embodiment of FIG. 3 shows a FPGA core, consisting of identical part elements, namely of a CLB 202, a CIP 208 and a configuration block 214. In all dual rail signals, which means the signals transmitted via lines 210, 204 and 206, it is ensured by the construction of the FPGA that the associated signals coding a value pair are layouted and guided identically, so that no difference in the current profile is generated when the one or the other signal switches. This applies always, particularly independent of the currently set configuration. As mentioned above, the statical configuration data can be passed on, by single rail signals to the CLBs 202 and the CIP 208, respectively, which reduces the layout effort and the area requirements.

With reference to the programming interface, it should be noted that also two separated interfaces can be provided for a separate setting of the configuration of the blocks and the connecting structure, instead of the common interface 16.

In other words, in the FPGA 10 of FIG. 1, all logic bits are coded as a value pair, wherein bits are then combined into the finally configured FPGA 10 by the logic blocks 18a-18d by maintaining this characteristic. Therefore, every CLB is designed in dual rail technique. Here, the logic (not shown), which determines the configuration of a CLB, can be designed in conventional single rail technique, since it does not switch during operation of the circuit and can thus not contribute to a data-dependent current consumption. The overall FPGA 10 is then combined from these CLBs as smallest subcircuits, wherein the connections between the CLBs are also programmable via the elements designated as CIP or PIP. Here, attention has to be paid that the two connections of a dual rail logic 18a-18d to the next stage, such as from a logic block 18a to logic block 18c, have the same length and are guided via the same number of CIPs, so that no new data dependences occur in the current consumption.

It should be noted that it has been described in the description of the previous embodiments with relation to the CIPs and those circuit parts within the CLBs responsible for configuration, that the same are realized in single rail technique. This applies in that the control signals passed on from the memory and the configuration block, respectively, to the same, are present in single rail coding. On the other hand, however, the CIPs and circuit parts within the CIPs are designed such that they maintain the dual rail coding of the data processed by the whole FPGA independent of the set configuration. In so far, it could be said that the CIPs and the circuit parts within the CLBs are present in dual rail technique. Taking up this approach, compared to conventional FPGA realizations, the circuits for CLBs and CIPs in the above-described embodiments are fully altered by the realization in dual rail technique, while the circuit technique for the configuration block part and the memory part, respectively, could be taken over mainly unchanged from an existing FPGA. The “DPA resistance” cannot be achieved in the same way by conventional FPGAs. According to the above embodiments, this property is valid independent of the actually used configuration, i.e. of the function realized by the FPGA. It requires no further considerations by the user programming the FPGA but is always given automatically. Compared to a conventional DPA resistant dual rail circuit in hardwired form, totally different application possibilities result in the previous embodiments due to the full reconfigurability of the FPGA. In contrary to a conventional dual rail circuit in hardwired form, which has only a very low configurability, if any at all, and thus has to be specifically designed for realizing a certain algorithm, the present embodiments allow the realization of any algorithm in a DPA resistant and unaltered way in one and the same circuit.

The above embodiments of FIGS. 1 and 3 refer to a FPGA resistant against DPA attacks as “stand alone” FPGA. However, the present invention can also be applied to an integrated FPGA module, which is only partly constructed in a DPA resistant way according to the described invention, wherein in the configuration of the FPGA it should be taken care that the subalgorithms to be protected come to lie within the DPA resistant part of the FPGA, while the unsecured part only processes non-DPA relevant data.

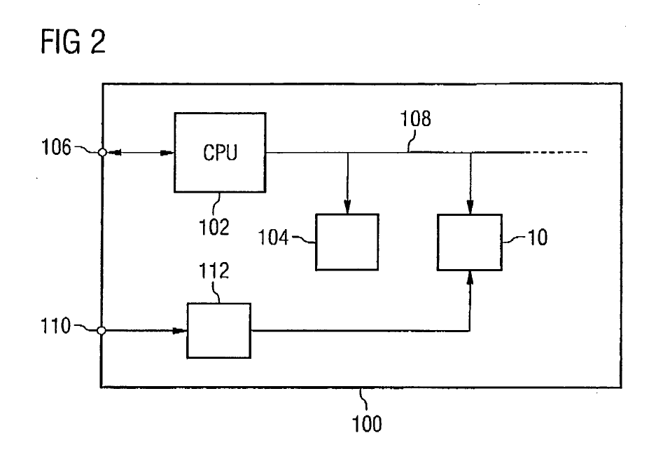

The embodiment described above with reference to FIG. 1 related merely to a FPGA 10, without addressing a more detailed application. FIG. 2 shows a possible embodiment, where an FPGA 10 is, for example, used as part of a cryptocontroller and chip card IC or security IC 100, respectively. The cryptocontroller 100 of FIG. 2 comprises a CPU 102, several peripheral units 104, such as coprocessors or the same, wherein in FIG. 2 exemplarily merely a peripheral unit 104 is shown, and the FPGA 10. A data/energy interface 106 of the cryptocontroller 100 is connected to the CPU 102, which is again connected to the peripheral units 104 and the FPGA 10 via a data bus 108.

For programming and configuring, respectively, the FPGA 10, the cryptocontroller 100 comprises an interface 110. An authorization control unit 112 is connected between interface 110 and the programming interface of the FPGA 10, which ensures that programming data to the FPGA 10 are performed only by authorized persons. An authorized person, such as the data issuer, is, for example, able to set the programming data of the FPGA 10 via an appropriate authentification compared to the unit 112 such that the same takes on a security critical function in the cryptocontroller 100, such as a payment function or the same. The CPU 102 performing the application of the cryptocontroller 100 can communicate with the input/output interface of the configured FPGA 10 via the data bus 108. The DPA resistance of the cryptocontroller 100 is maintained, since the FPGA 10, as described above, is DPA resistant.

With reference to FIG. 2, it should be noted that an individually provided interface 110 of the cryptocontroller 100 does not have to be provided for configuring the FPGA 10, but that the configuration and reconfiguration of the FPGA 10 can also be performed via the data interface 106, i.e. via the interface which is otherwise provided for communication between the cryptocontroller 100 and terminal or the same. The task of authorization checking of the unit 112 could in that case be performed by the CPU 102.

With regard to the above description, it should be noted that the present invention is not limited to reconfigurable FPGAs, but can also be used in logic, which is only once programmable, which means generally in user programmable logic (UPLs) and function programmable circuits, respectively. Thus, in the above embodiment, a memory 28 can also be a ROM or a PROM.

Further, FPGAs according to the present invention can be all known FPGA types, such as SRAM, anti-fuse or flash based FPGA types. The difference between SRAM, anti-fuse or flash based FPGAs lies in the actual realization of the memory in the embodiment of FIG. 1 or the configuration blocks in the embodiment of FIG. 3. Further, the present invention is not limited to FPGAs as configurable logic circuits. Thus, it would be possible that the connecting structure 20 of FIG. 1 is not configurable. Conversely, it would be possible that none of the logic blocks is configurable, but merely the connecting structure.

Additionally, an inventive configurable logic circuit can be implemented in any technology, which means not only in CMOS, where every transistor switching operation contributes to the current consumption of the configurable logic circuit, but also in others having a current consumption depending on the processed data.

While this invention has been described in terms of several preferred embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

1. A configurable logic circuit having a plurality of logic blocks and a connecting structure, via which the logic blocks are interconnectable, wherein the logic blocks are implemented in dual rail technique.

2. The configurable logic circuit according to claim 1, wherein every logic block has at least a pair of terminals, to receive or output a dual rail coded signal, wherein the connecting structure is configurable to connect the logic blocks in such a way that pairs of terminals are connected in pairs.

3. The configurable logic circuit according to claim 2, further comprising a first programming interface for configuring the connecting structure, such that a reconfiguration at the first programming interface leads at least to a reconnection of both terminals of a pair of terminals.

4. The configurable logic circuit according to claim 3, wherein at least one of the logic blocks is a configurable logic block, further having a second programming interface for configuring the configurable logic block.

5. The configurable logic circuit according to claim 4, wherein the first and second programming interfaces form a common programming interface.

6. The configurable logic circuit according to claim 3, wherein the connecting structure is reconfigurable and has a first circuit coupled to the first programming interface and is embodied in single rail technique.

7. A configurable logic circuit according to claim 4, wherein the configurable logic blocks are reconfigurable and have a second circuit connected to the second programming interface and embodied in single rail technique.

8. The configurable logic circuit according to claim 1, which is integrated in a chip together with a cryptography processor.

9. The configurable logic circuit according to claim 1, wherein the connecting structure is formed such that independent of a configuration of the connecting structure, every connection of a first terminal of a first pair of terminals to a first terminal of a second pair of terminals passes across just as many configurable connection nodes as the respective connection of the second terminal of the first pair of terminals to a second terminal of the second pair of terminals.

10. The configurable logic circuit according to claim 1, wherein the connecting structure is further formed such that independent of a configuration of the connecting structure, every connection of the first terminal of the first pair of terminals to the first terminal of the second pair of terminals has exactly the same length as a connection of the second terminal of the first pair of terminals to a second terminal of the second pair of terminals.

11. The configurable logic circuit according to claim 1, based on an integration technology, where every transistor switching operation contributes to the current consumption of the configurable logic circuit.

12. A configurable logic circuit comprising:
a plurality of logic blocks; and
a connecting means for interconnecting the logic blocks, wherein the logic blocks are implemented in dual rail technique.

13. The configurable logic circuit according to claim 12, wherein every logic block has at least a pair of terminals, to receive or output a dual rail coded signal, wherein the connecting means is configurable to connect the logic blocks in such a way that pairs of terminals are connected in pairs.

14. The configurable logic circuit according to claim 13, further comprising a first programming interface means for configuring the connecting means, such that a reconfiguration at the first programming interface means leads at least to a reconnection of both terminals of a pair of terminals.

15. The configurable logic circuit according to claim 14, wherein at least one of the logic blocks is a configurable logic block, further having a second programming interface means for configuring the configurable logic block.

16. The configurable logic circuit according to claim 15, wherein the first and second programming interface means form a common programming interface means.

17. The configurable logic circuit according to claim 14, wherein the connecting means is reconfigurable and has a first circuit coupled to the first programming interface means and is embodied in single rail technique.

18. A configurable logic circuit according to claim 15, wherein the configurable logic blocks are reconfigurable and have a second circuit connected to the second programming interface means and embodied in single rail technique.

19. The configurable logic circuit according to claim 12, which is integrated in a chip together with a cryptography processor.

20. The configurable logic circuit according to claim 12, wherein the connecting means is formed such that independent of a configuration of the connecting means, every connection of a first terminal of a first pair of terminals to a first terminal of a second pair of terminals passes across just as many configurable connection nodes as the respective connection of the second terminal of the first pair of terminals to a second terminal of the second pair of terminals.

21. The configurable logic circuit according to claim 12, wherein the connecting means is further formed such that independent of a configuration of the connecting means, every connection of the first terminal of the first pair of terminals to the first terminal of the second pair of terminals has exactly the same length as a connection of the second terminal of the first pair of terminals to a second terminal of the second pair of terminals.

22. The configurable logic circuit according to claim 12, based on an integration technology, where every transistor switching operation contributes to the current consumption of the configurable logic circuit.

23. A cryptocontroller comprising:
a central processing unit having a data interface connected thereto;
a configurable logic circuit, as claimed in claim 1, connected to the central processing unit; and
an authorization control unit, having a programming and configuring interface connected thereto, for ensuring that programming of the configurable logic circuit is performed only by authorized persons.

24. The cryptocontroller of claim 23, further comprising at least one peripheral unit connected to the central processing unit and the configurable logic circuit.
